(19) United States
(12) Patent Application Publication
(10) Pub. No.: US 2026/0280548 A1
(43) Pub. Date: Sep. 17, 2026

(54) METHOD FOR OPERATING AN ELECTRIC CIRCUIT

(71) Applicant: Infineon Technologies AG, Neubiberg (DE)

(72) Inventor: Klaus Hoermaier, Krumpendorf (AT)

(21) Appl. No.: 19/537,293

(22) Filed: Feb. 11, 2026

(30) Foreign Application Priority Data
Mar. 14, 2025 (DE) 102025109777.1

(51) Int. Cl. H03K 17/0812; H03K 17/08

(52) U.S. Cl. CPC H03K 17/08122; H03K 2017/0806; H03K 2217/0027; H03K 2217/0063; H03K 2217/0072; H03K 2217/0081

(57) ABSTRACT

The invention relates to a method for operating an electric circuit, the electric circuit comprising a low voltage domain and a high voltage domain. The electronic circuit is configured to perform a monitoring routine for detecting a short circuit condition between the low voltage domain and the high voltage domain and to perform a short circuit routine upon detection of a short circuit.

### TECHNICAL FIELD

This disclosure generally relates to the operation of an electric circuit including a low voltage domain and a high voltage domain, and, more specifically, to the operation of such an electric circuit in a short circuit event.

### BACKGROUND

Electric circuits, that include both a low voltage domain and a high voltage domain, are to be found in various fields of application and in particular in the field of the automobile industry. This is because in an automobile for example, a large number of loads are present, which are being laid out for different electric power consumption and supply voltage. Loads with high power consumption are often operated within the high voltage domain rather than within the low voltage domain in order to reduce electric current and with it electric losses. Different voltage domains are typically isolated from each other to ensure proper and interference-free operation of components designed for specific voltage levels.

Accordingly, an above noted electric circuit is laid out for at least two supply voltages, namely a low supply voltage, which is provided to the low voltage domain and a high supply voltage, which is provided to the high voltage domain. The low voltage domain includes all components of the electric circuit, that are supplied by the high supply voltage. The high voltage domain includes all components of the electric circuit, that are supplied by the low supply voltage.

In each voltage domain a plurality of electric loads need to be switched ON and OFF independently. For this, the low voltage domain comprises at least one low voltage domain switch with a low voltage domain transistor and a high voltage domain switch with a high voltage domain transistor. Due to the difference in voltage, which in an automobile may, for example be a low supply voltage of 12V vs. a high supply voltage of 48V, any short circuit on the output side of the switches imposes considerable risks to the loads and the switches, but also a potential fire hazard due to heat dissipation and arcing. Such a short circuit may have different causes and may be permanent or temporary.

Known from the state of the art are smart switches, which provide overcurrent or short circuity protection between the associated power supply and a ground potential or other loads as part of their protection functions. An above noted short circuit between voltage domains on the output side of the respective switches cannot to detected by those state of the art smart switches.

### SUMMARY

In general, this disclosure describes techniques for effectively operating an electric circuit, which electric circuit includes a low voltage domain and a high voltage domain. A short circuit criterion is defined, which indicates a short circuit between the low voltage domain and the high voltage domain, in particular a short circuit between the voltage domains on their respective output sides. This means, that such a short circuit between the voltage domains causes the short circuit criterion to be fulfilled.

In a monitoring routine, monitoring voltages and/or monitoring currents are being measured and evaluated in view of fulfilling the short circuit criterion regarding a short circuit between the voltage domains. In case of the short circuit criterion being fulfilled, a short circuit routine is being initiated. The circuit routine may include measures to reduce the negative impact of the short circuit. By evaluating the monitoring voltages and/or monitoring currents in view of a short circuit criterion, which directly corresponds to a short circuit between the voltage domains, in particular a short circuit between the voltage domains on their respective output sides, a safe detection of the short circuit and an appropriate reaction can be guaranteed, in order to prevent harm from the loads and the switches and in order to prevent a potential fire hazard due to heat dissipation and arcing.

In one example, this disclosure describes a method for operating an electric circuit, the electric circuit comprising a low voltage domain and a high voltage domain, the method comprising: providing the low voltage domain of the electric circuit with a low supply voltage; providing the high voltage domain of the electric circuit with a high supply voltage; providing a low voltage domain switch with a low voltage domain transistor for switching the low supply voltage for a low voltage domain load; providing a high voltage domain switch with a high voltage domain transistor for switching the high supply voltage for a high voltage domain load; controlling the low voltage domain switch and the high voltage domain switch individually into an ON state and an OFF state; in a monitoring routine, measuring a monitoring voltage and/or a monitoring current of the low voltage domain transistor and/or of the high voltage domain transistor of the high voltage domain switch and evaluating, if the monitoring voltage and/or the monitoring current of the low voltage domain transistor and/or the high voltage domain transistor of the high voltage domain switch fulfill(s) a short circuit criterion, which short circuit criterion indicates a short circuit between the low voltage domain and the high voltage domain, and, if the result of the evaluation is positive, initiating a short circuit routine.

In another example, this disclosure describes a smart switch for an electric circuit, the electric circuit comprising a low voltage domain and a high voltage domain, the smart switch comprising: a load transistor configured to being switched into an ON state and an OFF state; and a control unit configured to, in a monitoring routine, measure a monitoring voltage and/or a monitoring current of the load transistor and evaluate, if the monitoring voltage and/or the monitoring current of the load transistor fulfill(s) a short circuit criterion, which short circuit criterion indicates a short circuit between the low voltage supply domain and the high voltage supply domain, and, if the result of the evaluation is positive, initiate a short circuit routine.

In another example, this disclosure describes a power distribution system for operating an electric circuit, the electric circuit comprising a low voltage domain and a high voltage domain, the power distribution system comprising: a low voltage port for providing low supply voltage to the low voltage domain; a high voltage port for providing high supply voltage to the high voltage domain; a low voltage domain switch with a load transistor for switching the low supply voltage for a low voltage domain load; a high voltage domain switch with a load transistor for switching the high supply voltage for a high voltage domain load; a control arrangement, configured to control the low voltage domain switch and the high voltage domain switch individually into an ON state and an OFF state; in a monitoring routine, measure a monitoring voltage and/or a monitoring current of the load transistor of the low voltage domain switch and/or of the load transistor of the high voltage domain switch and evaluate, if the monitoring voltage and/or the monitoring current of the load transistor of the low voltage domain switch and/or the load transistor of the high voltage domain switch fulfill(s) a short circuit criterion, which short circuit criterion indicates a short circuit between the low voltage supply domain and the high voltage supply domain, and, if the result of the evaluation is positive, initiate a short circuit routine.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1 in a circuit diagram, an electric circuit with a proposed power distribution system for performing the proposed method,

FIG. 2 in a detailed flowchart representation, the monitoring routine and the short circuit routine of an embodiment of the proposed method,

FIG. 3 in a graph, the drain-source voltage of the low supply voltage switch according to the embodiment of FIG. 2,

FIG. 4 in a detailed flowchart representation, the monitoring routine and the short circuit routine of another embodiment of the proposed method and

FIG. 5 in a circuit diagram, a proposed switch.

### DETAILED DESCRIPTION

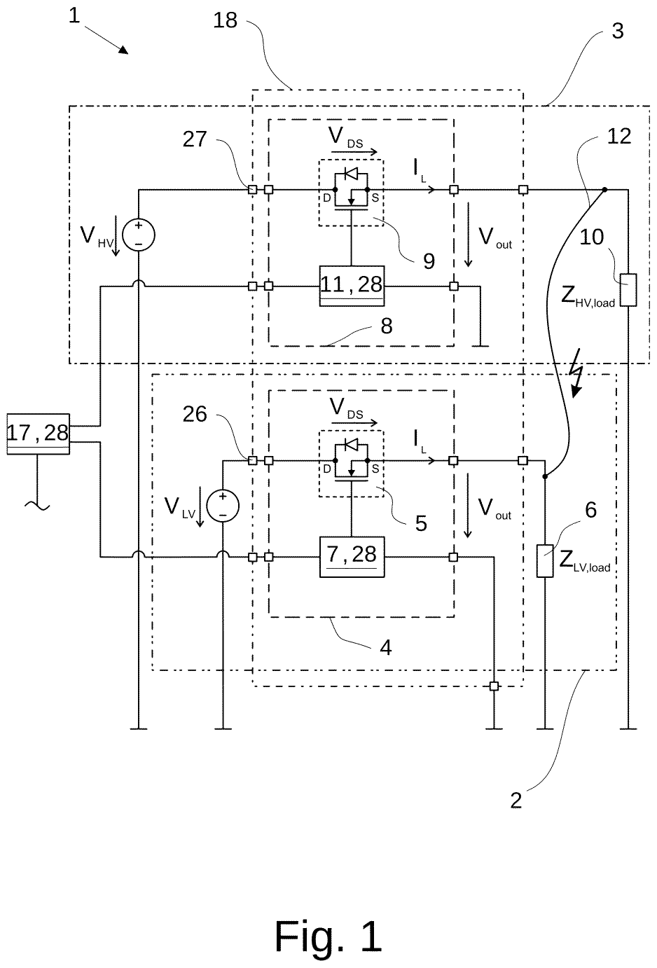

The electric circuit 1 shown in FIG. 1 may be part of a control of an automobile to drive various electric loads 6,10 such as electric actuators, in particular motors, electric heating elements, electric lighting equipment etc. It comprises a low voltage domain 2, for example to realize comfort functions such as an electric window lifter or an electric seat adjustment, and a high voltage domain 3, for example to realize an electric drive train for motion control of the automobile itself. Other fields of application are well possible for the electric circuit 1.

As noted above, the low voltage domain 2 and the high voltage domain 3 are defined by being provided with a low supply voltage V_{LV} and a high supply voltage V_{HV}, respectively. For an automotive application, for example, the low supply voltage V_{LV} may be about 12V and the high supply voltage V_{HV} may be about 48V. The low supply voltage V_{LV} and the high supply voltage V_{HV} may be provided by separate batteries, separate inverter circuits or the like.

The low voltage domain 2 comprises a low voltage domain switch 4 with a low voltage domain transistor 5 for switching the low supply voltage V_{LV} for a low voltage domain load 6. The low voltage domain switch 4, here and preferably, also comprises a low voltage domain control unit 7, which provides various control functions for the low voltage domain switch 4. The low voltage domain 2 is not limited to one low voltage domain switch 4 but may comprise a number of low voltage domain switches 4.

Equally, the high voltage domain 3 comprises a high voltage domain switch 8 with a high voltage domain transistor 9 for switching the high supply voltage V_{HV} for a high voltage domain load 10. The high voltage domain switch 8, here and preferably, also comprises a high voltage domain control unit 11, which provides various control functions for the high voltage domain switch 8 as noted above for the low voltage domain switch 4. The low voltage domain 2 is not limited to one high voltage domain switch 8 but may comprise a number of high voltage domain switches 8.

The high voltage domain switch 8 and the low voltage domain switch 4 with the additional logic through the low voltage domain control unit 7 and the high voltage domain control unit 11 are designed as a smart switches. Those control units 7,11 may provide various control functions such as protective functions based on current and voltage measurements, for example.

With those at least two switches 4,8, as depicted in FIG. 1, the low voltage domain load 6 and the high voltage domain load 10 may flexibly be controlled by controlling the low voltage domain switch 4 and the high voltage domain switch 8 individually into an ON state and an OFF state. In this example, both switches 4,8 are implemented as high side switches. Also, both switches 4,8 are each realized as a Field-Effect-Transistor like a MOSFET.

Even if an electric circuit 1 is well-designed in regard to the different voltages, an error or impurity may lead to an event of a short circuit 12 between the low voltage domain 2 and the high voltage domain 3, in particular between the output side of the low voltage domain transistor 5 and the high voltage domain transistor 9. Due to the difference between the low supply voltage V_{LV} and the high supply voltage V_{HV}, high currents and even arcs may result with the above noted risks.

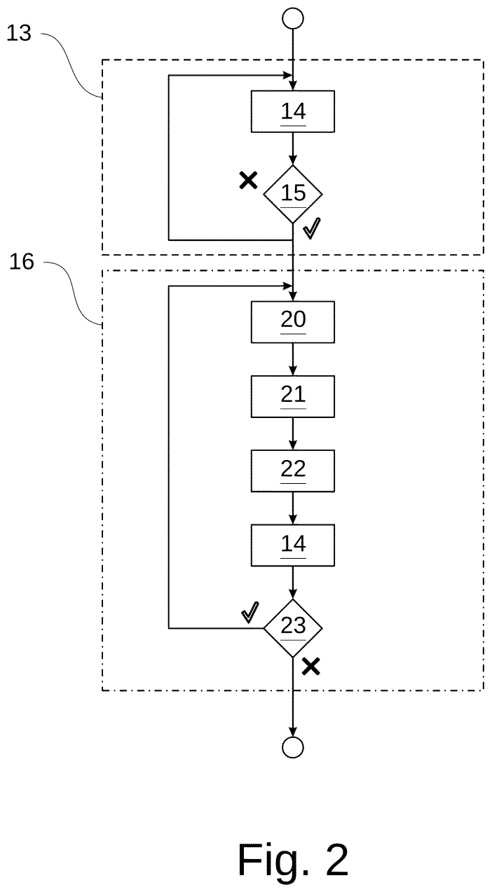

To handle those risks, a method according to the disclosure is proposed and shown in FIG. 2. A monitoring routine 13 is being performed, which includes a measuring step 14 in order to retrieve measuring data and an evaluation step 15 to decide about the fulfillment of a short circuit criterion. If the short circuit criterion is fulfilled, a short circuit routine 16 is initiated.

The short circuit criterion indicates a short circuit 12 between the low voltage domain 2 and the high voltage domain 3. This means that a predefined short circuit event leads to the fulfillment of the short circuit criterion. In the example shown in FIG. 1, the short circuit event goes back on establishing a short circuit 12 between the output side of the low voltage domain transistor 5 and the output side of the high voltage domain transistor 9.

It has been found, that an above noted short circuit criterion may be based on voltages and currents at the low voltage domain transistor 5 and/or the output side of the high voltage domain transistor 9. Accordingly, as a general concept it is proposed, in the monitoring routine 13, to measure a monitoring voltage and/or a monitoring current of the low voltage domain transistor 5 and/or of the high voltage domain transistor 9 and evaluating, if the monitoring voltage and/or the monitoring current of the low voltage domain transistor 5 and/or the high voltage domain transistor 9 fulfill(s) a short circuit criterion.

It is noteworthy that the evaluation, whether a short circuit criterion is fulfilled, may be performed within the low voltage domain switch 4 and/or the high voltage domain switch 8 without the need of additional control components. Each switch 4,8 operates basically on its own and doesn't need knowledge of other switches 4,8. Moreover, the switches 4,8 may not need the explicit configuration as a low voltage domain switch 4 or high voltage domain switch 8. The respective monitoring routine 13 and short circuit routine 16 are being performed by the low voltage domain control unit 7 and the high voltage domain control unit 11 respectively.

However, it is well possible to include additional control components such as a control device 17, which is shown in FIG. 1 and realized as an external control device 17 with respect to the low voltage domain switch 4 and the high voltage domain switch 8.

The short circuit routine 16 may follow different strategies, which leads to different implementations. One strategy is to protect the switching components of the electric circuit 1, in particular the low voltage domain switch 4. Another strategy is to protect the low voltage domain load 6 and possibly the high voltage domain load 10, which may be necessary, if those loads 6,10 do not have their own overvoltage or overcurrent protection. In the embodiments to be described, the focus is on the protection of the switching components of the electric circuit 1.

It may be taken from FIG. 1, that the electric circuit 1 provides a power distribution system 18, which is connected to the low supply voltage V_{LV}, the high supply voltage V_{HV}, the optional, external control device 17, the low voltage domain load 6 and the high voltage domain load 10. The power distribution system 18 may receive control signals from the control device 17 for individually switching the low voltage domain switch 4 and the high voltage domain switch 8 and may control the low voltage domain load 6 and the high voltage domain load 10 at the output side of the low voltage domain transistor 5 and the high voltage domain transistor 9. The power distribution system 18 may be realized as a self-contained module, which is in part or completely realized as an integrated semiconductor device or printed circuit board (PCB).

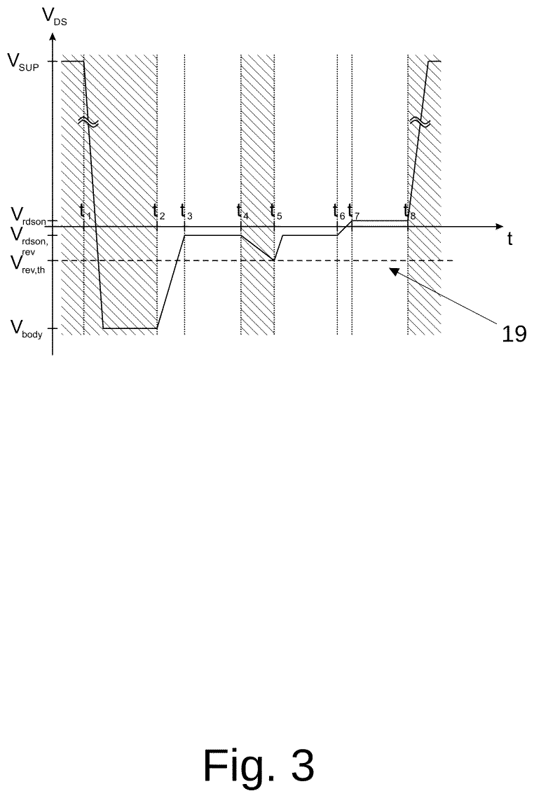

In the following aspect of the disclosure, the monitoring routine 13 and the short circuit routine 16 are focusing on the low voltage domain transistor 5. This aspect is explained with respect to FIGS. 1 to 3. While FIG. 2 shows the flowchart of the preferred method, FIG. 3 shows a graph of the drain-source voltage V_{DS} of the low voltage domain transistor 5 for the illustration of the effect of the routine.

Here and preferably, the monitoring voltage is defined as the drain-source voltage V_{DS} of this low voltage domain transistor 5 in its OFF state. In case of a short circuit 12 (as shown in FIG. 1) and with the high voltage domain transistor 9 in its ON state, the high supply voltage V_{HV} is also applied to the source of the low voltage domain transistor 5. If the low voltage domain transistor 5 in its OFF state, this causes a reverse current through its body diode and a resulting reverse voltage V_{DS} of the low voltage domain transistor 5. In FIG. 3, which illustrates the drain-source voltage V_{DS} of the low voltage domain transistor 5 over time, the shaded areas depict the OFF state of the low voltage domain transistor 5 and the non-shaded areas its ON state. At time t₁, the short circuit 12 is established and the high voltage domain transistor 9 is in its ON state. By this, the change of the drain-source voltage V_{DS} from the positive high supply voltage V_{HV} to a negative reverse voltage is triggered. This means, that the short circuit 12 may well be detected in the evaluation step 15 by analyzing the drain-source voltage V_{DS} of the low voltage domain transistor 5.

Accordingly, in one preferred embodiment, it is proposed that a short circuit criterion is fulfilled, if the monitoring voltage is a reverse voltage of the low voltage domain transistor 5. In particular, the short circuit criterion is fulfilled, if the magnitude of the reverse voltage is equal to or is exceeding a reverse voltage threshold 19 shown in FIG. 3. In addition or as an alternative, the short circuit criterion is fulfilled, if the magnitude of the reverse voltage increases with time.

In any case, the fulfillment of the short circuit criterion may be detected with low effort in the evaluation step 15, by the low voltage domain control unit 7, for example. Upon fulfillment of the short circuit criterion, the short circuit routine 16 is initiated as shown in FIG. 2.

The short circuit routine 16 shown in FIG. 2 takes into account, that the reverse current of the low voltage domain transistor 5 is not recommended for permanent operation. Such a reverse current through the body diode of the low voltage domain transistor 5 causes considerable heat dissipation and potential damage to the low voltage domain transistor 5. Accordingly, as a self-protection, the high reverse current through the body diode has to be limited to a very short time by controlling the low voltage domain transistor 5 into the ON state in a switch ON step 20 followed by a waiting step 21 shown in FIG. 2. In the graph of FIG. 3, the switch ON step 20 starts in t₂ and finishes in t₃, while the waiting step 21 is performed between t₃ and t₄. During t₂ and t₃ the charge of the gate of the MOSFET is changed to establish a R_{dson} channel. The switch ON step 20 reduces the power loss and heat dissipation and prevents the low voltage domain transistor 5 to be damaged, as the ohmic resistance R_{dson} of the low voltage domain transistor 5 compared to the body diode is very low.

As noted above, a short circuit 12 may well be temporary such that it is desirable to detect the continued existence or the elimination of the short circuit 12. If the short circuit 12 does not exist anymore, the forced ON state as a self-protection function of the low voltage domain transistor 5 should be ended to re-establish a normal operation. As the drain-source voltage V_{DS} during the ON state of the low voltage domain transistor 5, with and without the presence of a short circuit 12, is too small to allow safe detection of the existence or elimination of the short circuit 12 (in FIG. 3 between t₅ and t₈), it is proposed to cyclically check the status of the short circuit 12. This is done by cyclically controlling the low voltage domain transistor 5 into the OFF state in a switch OFF step 22 (in t₄ and t₈ in FIG. 3), followed by a subsequent measuring step 14 and a subsequent evaluation step 23. Controlling the low voltage domain transistor 5 5 into the OFF state means, to change the charge of the gate of the associated MOSFET towards an OFF state. The MOSFET does not need to be switched off entirely. In the subsequent measuring step 14, the drain-source voltage V_{DS} of the low voltage domain transistor 5 is measured, while in the subsequent evaluation step 23, it is evaluated, if the drain-source voltage V_{DS} of the low voltage domain transistor 5 is a reverse voltage, and, if so, if the magnitude of the reverse voltage is equal to or is exceeding a threshold, which may be the above noted reverse voltage threshold 19 shown in FIG. 3. If the result of the evaluation is negative, it is assumed that the short circuit 12 is eliminated, such that the short circuit routine 16 is terminated and the further process is being continued with the monitoring routine 13. In the graph of FIG. 3, the short circuit 12 is eliminated in t₆, which can be seen as the drain-source voltage V_{DS} becomes positive again. This positive voltage is still too small to allow a safe detection of the elimination of the short circuit 12. But the elimination can be evaluated after the switch OFF step 22 after t₈. It may be pointed out, that the elimination of the reverse voltage may be detected directly by measuring the drain-source voltage V_{DS} of the low voltage domain transistor 5 as noted above and indirectly by measuring the gate-source voltage of the low voltage domain transistor 5 for example.

It is to be noted, that during the cyclic switch OFF step 22, the low voltage domain transistor 5 does not need to be switched to the OFF state entirely, as explained above. It may well be, that the switch ON step 20 is already being initiated again, when the magnitude of the reverse voltage has exceeded the reverse voltage threshold 19, as the magnitude of the reverse voltage is high enough to allow a safe detection.

Preferably, the cyclical switching is defined by cycle ON time, during which the low voltage domain transistor 5 of the low voltage domain 2 is controlled into the ON state, and cycle OFF time, during which the low voltage domain transistor 5 of the low voltage domain 2 is controlled into the OFF state. As the risk of damage for the low voltage domain transistor 5 is much higher in the OFF state compared to the ON state, it is further preferred, that the cycle ON time is longer than the cycle OFF time, in particular by at least factor 2.

In the following aspects of the disclosure, the monitoring routine 13 and the short circuit routine 16 are focusing on the high voltage domain transistor 9, which monitoring routine 13 and short circuit routine 16 may well be performed in addition or as an alternative to the previously described routines.

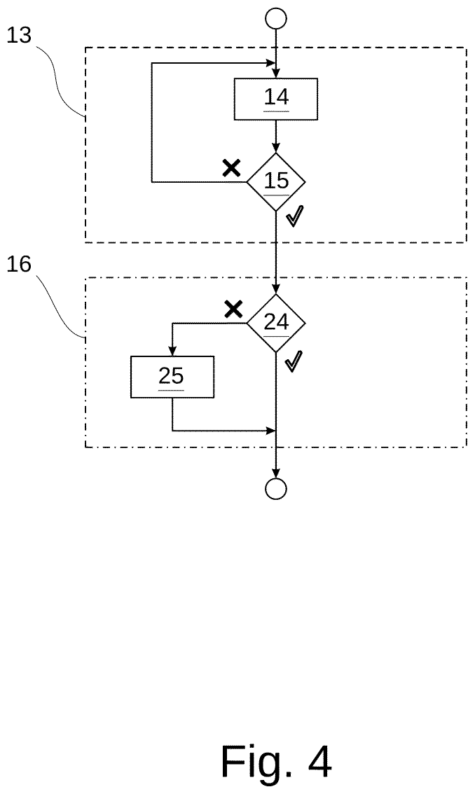

In one preferred option, the monitoring voltage is an output voltage Vₒᵤₜ of the high voltage domain transistor 9 in its OFF state. If a short circuit 12 shown in FIG. 1 is established, the low supply voltage V_{LV} is applied to the source of the high voltage domain transistor 9, if the low voltage domain transistor 5 is in the ON state. Accordingly, this short circuit 12 may easily be detected by measuring the output voltage Vₒᵤₜ of the high voltage domain transistor 9, which here and preferably is the voltage of the source of the high voltage domain transistor 9 vs. ground. Referring to FIG. 4, in the measuring step 14, the output voltage Vₒᵤₜ of the high voltage domain transistor 9 in its OFF state is being measured. The short circuit criterion is preferably fulfilled, if the output voltage Vₒᵤₜ of the high voltage domain transistor 9 is equal to or is exceeding an output voltage threshold. In the evaluation step 15 shown in FIG. 4, the output voltage Vₒᵤₜ of the high voltage domain transistor 9 is evaluated in view of this short circuit criterion. If the result of the evaluation is positive, a short circuit routine 16 is initiated.

In another preferred option, the monitoring voltage is an output voltage Vₒᵤₜ of the high voltage domain transistor 9 in its ON state. If a short circuit 12 shown in FIG. 1 is established, the output voltage Vₒᵤₜ may collapse (due to low resistance characteristics of the voltage source for the low supply voltage V_{LV}) such that the gradient of the output voltage Vₒᵤₜ of the high voltage domain transistor 9 may give an indication for the existence of such short circuit 12. Accordingly it is preferred, that the short circuit criterion is fulfilled, if the gradient of the output voltage Vₒᵤₜ with respect to time is equal to or is exceeding an output voltage gradient threshold.

In another preferred option, the monitoring current is the load current I_{L} through the high voltage domain transistor 9 in its ON state. If a short circuit 12 shown in FIG. 1 is established, the high supply voltage V_{HV} not only drives the high voltage domain load 10, but also the low voltage domain load 6 in parallel to the high voltage domain load 10. Accordingly, establishing an above noted short circuit 12 leads to a rise in load current I_{L} through the high voltage domain transistor 9. Therefore according to another embodiment it is preferred, that the short circuit criterion is fulfilled, if the gradient of the load current I_{L} with respect to time is equal to or is exceeding a load current I_{L} gradient threshold.

According to one embodiment it is proposed that the output voltage threshold of the high voltage domain transistor 9 in its OFF state is below the low supply voltage V_{LV} and/or between 70% and 140% of the low supply voltage V_{LV}. This advantageously allows for early detection of a potential short circuit condition between the low voltage domain 2 and the high voltage domain 3, as even a slight rise in output voltage Vₒᵤₜ can be indicative of an impending short circuit 12.

As the high voltage domain switch 8 is less likely in risk of being damaged by the above noted short circuit 12, in the short circuit 12 of the high voltage domain switch 8, protecting the low voltage domain switch 4 is in focus. According to a preferred embodiment, in the short circuit routine 16, the high voltage domain transistor 9 is kept in the OFF state or controlled into the OFF state. This is shown inf FIG. 4, which for the short circuit routine 16 shows a status evaluation step 24 for the high voltage domain transistor 9 and, if the switching status is not the OFF state, a status change step 25 into the OFF state. This ensures a protection of the low voltage domain transistor 5 against the high supply voltage V_{HV} in the case of a short circuit condition.

In addition or as an alternative, in the short circuit routine 16, if the short circuit criterion ceases to being fulfilled, the short circuit routine 16 is being terminated and the monitoring routine 13 is being continued. According to this embodiment, the short circuit routine 16 is not left until the short circuit 12 has been eliminated, which safely prevents unintended control of the high voltage domain transistor 9 into the ON state during the short circuit condition.

According to one embodiment it is proposed in the short circuit routine 16, a short circuit control signal is being generated and transmitted to another control component. This allows for the integration of the method with existing control systems, enabling a comprehensive and system-wide response to the short circuit condition.

According to one embodiment it is proposed that the magnitude of the high supply voltage V_{HV} is at least 2 times or at least 3 times the magnitude of the low supply voltage V_{LV}. In those cases of relatively large voltage differences between the low supply voltage V_{LV} and the high supply voltage V_{HV}, the proposed solution is of considerable benefit in view of damage prevention.

In the explanations given above, a number of measures have been proposed in order to detect a short circuit condition in the monitoring routine 13 and to react to this detection in a short circuit routine 16. All of those measures may be combined according to the kind of application and in particular to the kind of loads 6,10 to be controlled. Accordingly, in a preferred embodiment, the control units 7,11 are configured to allow partially or entirely switching on and off monitoring routines 13 and short circuit routines 16 on demand.

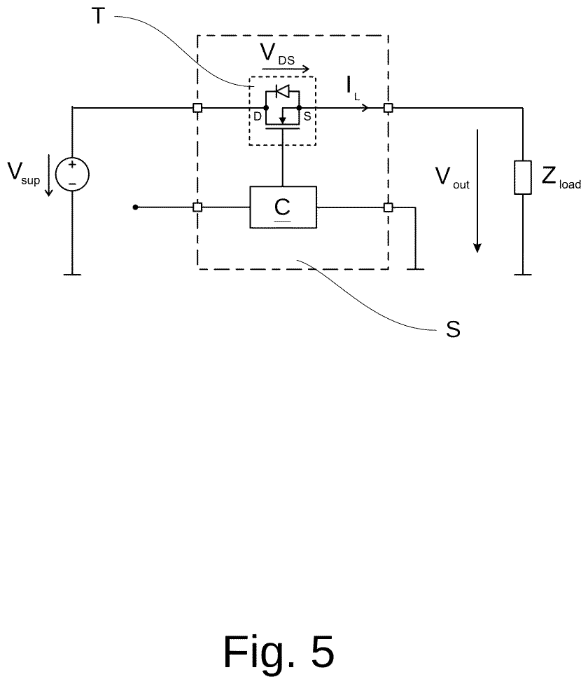

Core components for the performance of the proposed method are the low voltage domain switch 4 and the high voltage domain switch 8 with their respective architecture as smart switches. Accordingly, another teaching relates to a smart switch S shown in FIG. 5. The smart switch S is assigned to an above noted electric circuit 1, which electric circuit 1 comprises a low voltage domain 2 and a high voltage domain 3. The smart switch S comprises a transistor T configured to being switched into an ON state and an OFF state and a control unit C. The control unit C is configured to, in a monitoring routine 13, measure a monitoring voltage and/or a monitoring current of the transistor T and evaluate, if the monitoring voltage and/or the monitoring current of the transistor T fulfill(s) a short circuit criterion, which short circuit criterion indicates a short circuit 12 between the low voltage domain 2 and the high voltage domain 3, and, if the result of the evaluation is positive, initiate a short circuit routine 16.

With the above noted basic structure, the proposed smart switch S may autonomously be used to realize the proposed method. This is because the control unit C of the smart switch S is configured to perform the monitoring routine 13 and/or the short circuit routine 16. As a result, the proposed method can be implemented by using a proposed smart switch S as a low voltage domain switch 4, which control unit C is configured, in particular programmed, for the low voltage domain routines and a proposed high voltage domain switch 8, which control unit C is configured, in particular programmed for the high voltage domain routines.

In order to provide the smart switch S as a comprehensive device suitable to mass production, in a preferred embodiment, the smart switch S, comprises, on a semiconductor substrate, at least the transistor T and the control unit C. Alternatively it may be advantageous in view of heat dissipation, that the smart switch S comprises, on a semiconductor substrate, at least the control unit C, and separately from the semiconductor substrate, the transistor T. In the latter case, preferably, the control unit C and the transistor T are arranged on a single PCB.

Preferably, the transistor T is a MOSFET, wherein the monitoring voltage is the drain-source voltage V_{DS} of the transistor T in its OFF state and wherein a short circuit criterion is fulfilled, if the monitoring voltage is a reverse voltage. This is a preferred configuration of the low voltage domain switch 4 noted above. All explanations given are fully applicable for the proposed smart switch S.

According to one embodiment the control unit C is configured to: in the short circuit routine 16, switch the transistor T into an ON state and cyclically switch the transistor T into an OFF state and, during the transistor T being in the OFF state, evaluate whether the monitoring voltage is a reverse voltage and, if the result of the evaluation is negative, leave the transistor T in the OFF state, terminating the short circuit routine 16 and continuing with the monitoring routine 13, preferably, wherein the cyclical switching is defined by cycle ON time, during which the transistor T is in the ON state, and cycle OFF time, during which the transistor T is in the OFF state and wherein the cycle ON time is longer than the cycle OFF time by at least factor 2. This is also a preferred configuration of the low voltage domain switch 4 noted above. Again, all explanations given are fully applicable for the proposed smart switch S.

In addition or as an alternative it is proposed, that the monitoring voltage is an output voltage Vₒᵤₜ of the transistor T in its OFF state and the short circuit criterion is fulfilled, if the output voltage Vₒᵤₜ of the transistor T is equal to or is exceeding an output voltage threshold, and/or, that the monitoring voltage is an output voltage Vₒᵤₜ of the transistor T in its ON state, and wherein the short circuit criterion is fulfilled, if the gradient of the output voltage Vₒᵤₜ with respect to time is equal to or is exceeding an output voltage gradient threshold, and/or, that the monitoring current is the load current I_{L} through the transistor T in its ON state and wherein the short circuit criterion is fulfilled, if the gradient of the load current I_{L} with respect to time is equal to or is exceeding a load current I_{L} gradient threshold. Those three options are preferred configurations of the high voltage domain switch 8 noted above. Again, all explanations given are fully applicable for the proposed smart switch S.

According to one embodiment it is proposed in the short circuit routine 16, the control unit C is configured to generate and output a short circuit control signal. As noted above, this allows for the integration of the method with existing control systems, enabling a comprehensive and system-wide response to the short circuit condition.

Another teaching which is of equal importance relates to the above noted power distribution system 18 as such for operating an electric circuit 1, the electric circuit 1 comprising a low voltage domain 2 and a high voltage domain 3. This power distribution system 18 is indicated in FIG. 1.

According to this independent teaching, the power distribution system 18 comprises a low voltage port 26 for providing a low supply voltage V_{LV} to the low voltage domain 2, a high voltage port 27 for providing a high supply voltage V_{HV} to the high voltage domain 3, a low voltage domain switch 4 with a low voltage domain transistor 5 for switching the low supply voltage V_{LV} for a low voltage domain load 6, a high voltage domain switch 8 with a high voltage domain transistor 9 for switching the high supply voltage V_{HV} for a high voltage domain load 10 and a control arrangement 28. In this embodiment, the power distribution system 18 comprises two switches 4,8 for two loads 6,10. However, the power distribution system 18 may comprise a larger number of switches 4,8 according to the number of loads 6,10 to be controlled.

The control arrangement 28 may be provided by the control units 7,11 of the switches 4,8. Depending on the application the external control device 17 may be part of the control arrangement 28 as well. All in all, the control arrangement 28 is configured to provide the monitoring routine 13 and the short circuit routine 16 described above. This means, that the control arrangement 28 is configured to, in a monitoring routine 13, measure a monitoring voltage and/or a monitoring current of the low voltage domain transistor 5 and/or of the high voltage domain transistor 9 and evaluate, if the monitoring voltage and/or the monitoring current of the low voltage domain transistor 5 and/or the high voltage domain transistor 9 fulfill(s) a short circuit criterion, which short circuit criterion indicates a short circuit 12 between the low voltage domain 2 and the high voltage domain 3, and, if the result of the evaluation is positive, initiate a short circuit routine 16. Reference is again made to the explanations given above.

According to one embodiment it is proposed that the low voltage domain switch 4 and the high voltage domain switch 8 are being realized as integrated semiconductor devices. This means, that the low voltage domain switch 4 comprises, on a semiconductor substrate, the low voltage domain transistor 5 and a low voltage domain control unit 7 as part of the control arrangement 28 configured to perform at least part of the monitoring routine 13 and/or at least part of the short circuit routine 16. Additionally, this means, that the high voltage domain switch 8 comprises, on a semiconductor substrate, the high voltage domain transistor 9 and a high voltage domain control unit 11 as part of the control arrangement 28 configured to perform at least part of the monitoring routine 13 and/or at least part of the short circuit routine 16.

As already explained, the power distribution system 18 in one preferred option comprises an external control device 17 as part of the control arrangement 28 configured to perform at least part of the monitoring routine 13 and/or at least part of the short circuit routine 16, which external control device 17 is realized separately at least from the low voltage domain switch 4 and the high voltage domain switch 8.

Finally, it may be pointed out, that the electric circuit 1 as such, including the loads 6,10 to be controlled, is subject to an independent teaching. Reference is made to all previous explanations regarding the electric circuit 1.

### EXAMPLES

### Example 1

A method for operating an electric circuit 1, the electric circuit 1 comprising a low voltage domain 2 and a high voltage domain 3, the method comprising:
providing the low voltage domain 2 of the electric circuit 1 with a low supply voltage V_{LV};
providing the high voltage domain 3 of the electric circuit 1 with a high supply voltage V_{HV};
providing a low voltage domain switch 4 with a low voltage domain transistor 5 for switching the low supply voltage V_{LV} for a low voltage domain load 6;
providing a high voltage domain switch 8 with a high voltage domain transistor 9 for switching the high supply voltage V_{HV} for a high voltage domain load 10;
controlling the low voltage domain switch 4 and the high voltage domain switch 8 individually into an ON state and an OFF state;
in a monitoring routine 13, measuring a monitoring voltage and/or a monitoring current of the low voltage domain transistor 5 and/or of the high voltage domain transistor 9 and evaluating, if the monitoring voltage and/or the monitoring current of the low voltage domain transistor 5 and/or the high voltage domain transistor 9 fulfill(s) a short circuit criterion, which short circuit criterion indicates a short circuit 12 between the low voltage domain 2 and the high voltage domain 3, and, if the result of the evaluation is positive, initiating a short circuit routine 16.

### Example 2

The method according to example 1, wherein the low voltage domain transistor 5 is a MOSFET, wherein the monitoring voltage is the drain-source voltage V_{DS} of this low voltage domain transistor 5 in its OFF state and wherein a short circuit criterion is fulfilled, if the monitoring voltage is a reverse voltage, preferably, wherein the short circuit criterion is fulfilled, if the magnitude of the reverse voltage is equal to or is exceeding a reverse voltage threshold 19, and/or, if the magnitude of the reverse voltage increases with time.

### Example 3

The method according to example 1 or 2, wherein in the short circuit routine 16, controlling the low voltage domain transistor 5 into an ON state and cyclically controlling the low voltage domain transistor 5 into an OFF state and, during the low voltage domain transistor 5 being in a transient state or the OFF state, evaluating whether the monitoring voltage is a reverse voltage and, if the result of the evaluation is negative, terminating the short circuit routine 16 and continuing with the monitoring routine 13, preferably, wherein the cyclical switching is defined by cycle ON time, during which the low voltage domain transistor 5 is controlled into the ON state, and cycle OFF time, during which the low voltage domain transistor 5 is controlled into the OFF state and wherein the cycle ON time is longer than the cycle OFF time, further preferably by at least factor 2.

### Example 4

The method according to any of examples 1-3, wherein the monitoring voltage is an output voltage Vₒᵤₜ of the high voltage domain transistor 9 in its OFF state and the short circuit criterion is fulfilled, if the output voltage Vₒᵤₜ of the high voltage domain transistor 9 is equal to or is exceeding an output voltage threshold,

and/or,
wherein the monitoring voltage is an output voltage Vₒᵤₜ of the high voltage domain transistor 9 in its ON state, and wherein the short circuit criterion is fulfilled, if the gradient of the output voltage Vₒᵤₜ with respect to time is equal to or is exceeding an output voltage gradient threshold,
   and/or,
wherein the monitoring current is the load current I_{L} through the high voltage domain transistor 9 in its ON state and wherein the short circuit criterion is fulfilled, if the gradient of the load current I_{L} with respect to time is equal to or is exceeding a load current I_{L} gradient threshold.

### Example 5

The method according to any of examples 1-4, wherein the output voltage threshold is below the low supply voltage V_{LV} and/or between 70% and 140% of the low supply voltage V_{LV}.

### Example 6

The method according to any of examples 1-5, wherein in the short circuit routine 16, the high voltage domain transistor 9 is kept in the OFF state or controlled into the OFF state, and/or, wherein, in the short circuit routine 16, if the short circuit criterion ceases to being fulfilled, the short circuit routine 16 is being terminated and the monitoring routine 13 is being continued.

### Example 7

The method according to any of examples 1-6, wherein in the short circuit routine 16, a short circuit control signal is being generated and transmitted to another control component.

### Example 8

The method according to any of examples 1-7, wherein the magnitude of the high supply voltage V_{HV} is at least 2 times or at least 3 times the magnitude of the low supply voltage V_{LV}.

### Example 9

Smart switch S for an electric circuit 1, the electric circuit 1 comprising a low voltage domain 2 and a high voltage domain 3, the smart switch S comprising:
a transistor T configured to being switched into an ON state and an OFF state;
   and
a control unit C configured to:
   in a monitoring routine 13, measure a monitoring voltage and/or a monitoring current of the transistor T and evaluate, if the monitoring voltage and/or the monitoring current of the transistor T fulfill(s) a short circuit criterion, which short circuit criterion indicates a short circuit 12 between the low voltage domain 2 and the high voltage domain 3, and, if the result of the evaluation is positive, initiate a short circuit routine 16.

### Example 10

The smart switch S according to example 9, wherein the smart switch S comprises, on a semiconductor substrate, at least the transistor T and the control unit C, or, wherein the smart switch S comprises, on a semiconductor substrate, the control unit C, and separately from the semiconductor substrate the transistor T.

### Example 11

The smart switch S according to example 9 or 10, wherein the transistor T is a MOSFET, wherein the monitoring voltage is the drain-source voltage V_{DS} of the transistor T in its OFF state and wherein a short circuit criterion is fulfilled, if the monitoring voltage is a reverse voltage.

### Example 12

The smart switch S according to examples 9-11, wherein the control unit C is configured to:
in the short circuit routine 16, switch the transistor T into an ON state and cyclically switch the transistor T into an OFF state and, during the transistor T being in the OFF state, evaluate whether the monitoring voltage is a reverse voltage and, if the result of the evaluation is negative, leave the transistor T in the OFF state, terminating the short circuit routine 16 and continuing with the monitoring routine 13, preferably, wherein the cyclical switching is defined by cycle ON time, during which the transistor T is in the ON state, and cycle OFF time, during which the transistor T is in the OFF state and wherein the cycle ON time is longer than the cycle OFF time by at least factor 2.

### Example 13

The smart switch S according to examples 9-12, wherein the monitoring voltage is an output voltage Vₒᵤₜ of the transistor T in its OFF state and the short circuit criterion is fulfilled, if the output voltage Vₒᵤₜ of the transistor T is equal to or is exceeding an output voltage threshold,

and/or,
wherein the monitoring voltage is an output voltage Vₒᵤₜ of the transistor T in its ON state, and wherein the short circuit criterion is fulfilled, if the gradient of the output voltage Vₒᵤₜ with respect to time is equal to or is exceeding an output voltage gradient threshold,
   and/or,
wherein the monitoring current is the load current I_{L} through the transistor T in its ON state and wherein the short circuit criterion is fulfilled, if the gradient of the load current I_{L} with respect to time is equal to or is exceeding a load current I_{L} gradient threshold.

### Example 14

The smart switch S according to examples 9-13, wherein in the short circuit routine 16, the control unit C is configured to generate and output a short circuit control signal.

### Example 15

Power distribution system 18 for operating an electric circuit 1, the electric circuit 1 comprising a low voltage domain 2 and a high voltage domain 3, the power distribution system 18 comprising:
a low voltage port 26 for providing a low supply voltage V_{LV} to the low voltage domain 2;
a high voltage port 27 for providing a high supply voltage V_{HV} to the high voltage domain 3;
a low voltage domain switch 4 with a low voltage domain transistor 5 for switching the low supply voltage V_{LV} for a low voltage domain load 6;
a high voltage domain switch 8 with a high voltage domain transistor 9 for switching the high supply voltage V_{HV} for a high voltage domain load 10;
a control arrangement 28, configured to:
in a monitoring routine 13, measure a monitoring voltage and/or a monitoring current of the low voltage domain transistor 5 and/or of the high voltage domain transistor 9 and evaluate, if the monitoring voltage and/or the monitoring current of the low voltage domain transistor 5 and/or the high voltage domain transistor 9 fulfill(s) a short circuit criterion, which short circuit criterion indicates a short circuit 12 between the low voltage domain 2 and the high voltage domain 3, and, if the result of the evaluation is positive, initiate a short circuit routine 16.

### Example 16

The power distribution system 18 according to example 15, wherein the low voltage domain switch 4 comprises on a semiconductor substrate:
the low voltage domain transistor 5 and a low voltage domain control unit 7 as part of the control arrangement 28 configured to perform at least part of the monitoring routine 13 and/or at least part of the short circuit routine 16,
   and
   wherein the high voltage domain switch 8 comprises on a semiconductor substrate:
the high voltage domain transistor 9 and a high voltage domain control unit 11 as part of the control arrangement 28 configured to perform at least part of the monitoring routine 13 and/or at least part of the short circuit routine 16.

### Example 17

The power distribution system 18 according to example 15 or 16, wherein the power distribution system 18 comprises an external control device 17 as part of the control arrangement 28 configured to perform at least part of the monitoring routine 13 and/or at least part of the short circuit routine 16, which external control device 17 is realized separately at least from the low voltage domain switch 4 and the high voltage domain switch 8.

### Example 18

Electric circuit 1 including a low voltage domain 2 and a high voltage domain 3, the electric circuit 1 comprising:
a low voltage domain load 6;
a high voltage domain load 10;
a low voltage port 26 for providing low voltage to the low voltage domain 2;
a high voltage port 27 for providing high voltage to the high voltage domain 3;
a low voltage domain switch 4 with a load 6,10 transistor T for switching the low voltage for the low voltage domain load 6;
a high voltage domain switch 8 with a load 6,10 transistor T for switching the high voltage for the high voltage domain load 10;
a control arrangement 28, configured to
control the low voltage domain switch 4 and the high voltage domain switch 8 individually into an ON state and an OFF state;
in a monitoring routine 13, measure a monitoring voltage and/or a monitoring current of the low voltage domain transistor 5 and/or of the high voltage domain transistor 9 and evaluate, if the monitoring voltage and/or the monitoring current of the low voltage domain transistor 5 and/or of the high voltage domain transistor 9 fulfill(s) a short circuit criterion and, if the result of the evaluation is positive, initiate a short circuit routine 16.

1. A method for operating an electric circuit, the electric circuit comprising a low voltage domain and a high voltage domain, the method comprising:
providing the low voltage domain of the electric circuit with a low supply voltage;
providing the high voltage domain of the electric circuit with a high supply voltage;
providing a low voltage domain switch with a low voltage domain transistor for switching the low supply voltage for a low voltage domain load;
providing a high voltage domain switch with a high voltage domain transistor for switching the high supply voltage for a high voltage domain load;
controlling the low voltage domain switch and the high voltage domain switch individually into an ON state and an OFF state;
in a monitoring routine, measuring a monitoring voltage and/or a monitoring current of the low voltage domain transistor and/or of the high voltage domain transistor and evaluating, if the monitoring voltage and/or the monitoring current of the low voltage domain transistor and/or the high voltage domain transistor fulfill(s) a short circuit criterion, wherein the short circuit criterion indicates a short circuit between the low voltage domain and the high voltage domain, and, if the result of the evaluation is positive, initiating a short circuit routine.

2. The method according to claim 1, wherein the low voltage domain transistor is a metal oxide semiconductor field effect transistor (MOSFET), wherein the monitoring voltage is the drain-source voltage of the low voltage domain transistor in its OFF state and wherein the short circuit criterion is fulfilled, if the monitoring voltage is a reverse voltage.

3. The method according to claim 1 further comprising: in the short circuit routine, controlling the low voltage domain transistor into an ON state and cyclically controlling the low voltage domain transistor into an OFF state and, during the low voltage domain transistor being in a transient state or the OFF state, evaluating whether the monitoring voltage is a reverse voltage and, if a result of the evaluation is negative, terminating the short circuit routine and continuing with the monitoring routine, wherein the cyclical switching is defined by cycle ON time, during which the low voltage domain transistor is controlled into the ON state, and cycle OFF time, during which the low voltage domain transistor is controlled into the OFF state and wherein the cycle ON time is longer than the cycle OFF time by at least factor 2.

4. The method according to claim 1, wherein the monitoring voltage is an output voltage of the high voltage domain transistor in its OFF state and the short circuit criterion is fulfilled, if the output voltage of the high voltage domain transistor is equal to or is exceeding an output voltage threshold,
and/or,
wherein the monitoring voltage is an output voltage of the high voltage domain transistor in its ON state, and wherein the short circuit criterion is fulfilled, if the gradient of the output voltage with respect to time is equal to or is exceeding an output voltage gradient threshold,
and/or,
wherein the monitoring current is a load current through the high voltage domain transistor in its ON state and wherein the short circuit criterion is fulfilled, if a gradient of the load current with respect to time is equal to or is exceeding a load current gradient threshold.

5. The method according to claim 4, wherein the output voltage threshold is below the low supply voltage and/or between 70% and 140% of the low supply voltage.

6. The method according to claim 1, wherein in the short circuit routine, the high voltage domain transistor is kept in the OFF state or controlled into the OFF state, and/or, wherein, in the short circuit routine, if the short circuit criterion ceases to be fulfilled, the short circuit routine is terminated and the monitoring routine continued.

7. The method according to claim 1, wherein in the short circuit routine a short circuit control signal is generated and transmitted to another control component.

8. The method according to claim 1, wherein a magnitude of the high supply voltage is at least 2 times a magnitude of the low supply voltage.

9. A smart switch for an electric circuit, the electric circuit comprising a low voltage domain and a high voltage domain, the smart switch comprising:
a transistor configured to being switched into an ON state and an OFF state;
and
a control unit configured to:
in a monitoring routine, measure a monitoring voltage and/or a monitoring current of the transistor and evaluate, if the monitoring voltage and/or the monitoring current of the transistor fulfill(s) a short circuit criterion, wherein the short circuit criterion indicates a short circuit between the low voltage domain and the high voltage domain, and, if the result of the evaluation is positive, initiate a short circuit routine.

10. The smart switch according to claim 9, wherein the smart switch comprises, on a semiconductor substrate, at least the transistor and the control unit, or, wherein the smart switch comprises, on the semiconductor substrate, the control unit, and separately from the semiconductor substrate, the transistor.

11. The smart switch according to claim 9, wherein the transistor is a metal oxide semiconductor field effect transistor (MOSFET), wherein the monitoring voltage is the drain-source voltage of the transistor in its OFF state and wherein a short circuit criterion is fulfilled, if the monitoring voltage is a reverse voltage.

12. The smart switch according to claim 11, wherein the control unit is configured to:
in the short circuit routine, switch the transistor into the ON state and cyclically switch the transistor into the OFF state and, during the transistor being in the OFF state, evaluate whether the monitoring voltage is a reverse voltage and, if the result of the evaluation is negative, leave the transistor in the OFF state, terminate the short circuit routine and continue with the monitoring routine, wherein the cyclical switching is defined by cycle ON time, during which the transistor is in the ON state, and cycle OFF time, during which the transistor is in the OFF state and wherein the cycle ON time is longer than the cycle OFF time by at least factor 2.

13. The smart switch according to claim 9, wherein the monitoring voltage is an output voltage of the transistor in its OFF state and the short circuit criterion is fulfilled, if the output voltage of the transistor is equal to or is exceeding an output voltage threshold,
and/or,
wherein the monitoring voltage is an output voltage of the transistor in its ON state, and
wherein the short circuit criterion is fulfilled, if a gradient of the output voltage with respect to time is equal to or is exceeding an output voltage gradient threshold,
and/or,
wherein the monitoring current is the load current through the transistor in its ON state and wherein the short circuit criterion is fulfilled, if a gradient of the load current with respect to time is equal to or is exceeding a load current gradient threshold.

14. The smart switch (S) according to claim 9, wherein in the short circuit routine, the control unit is configured to generate and output a short circuit control signal.

15. A power distribution system for operating an electric circuit, the electric circuit comprising a low voltage domain and a high voltage domain, the power distribution system comprising:
a low voltage port for providing a low supply voltage to the low voltage domain;
a high voltage port for providing a high supply voltage to the high voltage domain;
a low voltage domain switch comprising a low voltage domain transistor for switching the low supply voltage for a low voltage domain load;
a high voltage domain switch comprising a high voltage domain transistor for switching the high supply voltage for a high voltage domain load;
a control arrangement configured to:
in a monitoring routine, measure a monitoring voltage and/or a monitoring current of the low voltage domain transistor and/or of the high voltage domain transistor and evaluate, if the monitoring voltage and/or the monitoring current of the low voltage domain transistor and/or the high voltage domain transistor fulfill(s) a short circuit criterion, wherein the short circuit criterion indicates a short circuit between the low voltage domain and the high voltage domain, and, if the result of the evaluation is positive, initiate a short circuit routine.

16. The power distribution system according to claim 15, wherein the low voltage domain switch comprises on a semiconductor substrate:
the low voltage domain transistor and a low voltage domain control unit as part of the control arrangement configured to perform at least part of the monitoring routine and/or at least part of the short circuit routine,
and
wherein the high voltage domain switch comprises on the semiconductor substrate:
the high voltage domain transistor and a high voltage domain control unit as part of the control arrangement configured to perform at least part of the monitoring routine and/or at least part of the short circuit routine.

17. The power distribution system according to claim 15, wherein the power distribution system comprises an external control device as part of the control arrangement configured to perform at least part of the monitoring routine and/or at least part of the short circuit routine, wherein the external control device is separate from at least from the low voltage domain switch and the high voltage domain switch.

18. The method of claim 1, wherein the short circuit criterion is fulfilled if the monitoring voltage is a reverse voltage and a magnitude of the reverse voltage is equal to or is exceeding a reverse voltage threshold.

19. The method of claim 1, wherein the short circuit criterion is fulfilled if the monitoring voltage is a reverse voltage and a magnitude of the reverse voltage increases with time.
